(19) United States
(12) Patent Application Publication
(10) Pub. No.: US 2004/0119384 A1
(43) Pub. Date: Jun. 24, 2004

(54) Bezel assembly

(76) Inventors: Richard W. Davis, San Jose, CA (US); Mark D. Feldmeyer, San Jose, CA (US)

Correspondence Address: HEWLETT-PACKARD COMPANY, Intellectual Property Administration, P.O. Box 272400, Fort Collins, CO, 80527-2400, US

(21) Appl. No.: 10/327,222

(22) Filed: Dec. 20, 2002

(51) Int. Cl. H05K 7/18

(52) U.S. Cl. 312/223.2; 312/265.5; 312/326

(57) ABSTRACT

The present invention provides a bezel assembly comprising a bezel having a first and second receiving members opositely disposed about a first side of the bezel. Each receiving member has a receptacle. The bezel assembly also comprises a mounting member. The mounting member comprises a body and a first and second engaging arm oppositely disposed at each end of the body. The receiving members provide for captive engagement of the mounting member such that the bezel may pivot more than ninety degrees between a closed and open position.

### FIELD OF THE INVENTION

Embodiments of the present invention relate to enclosures for electrical and electronic device, and more particularly to an enclosure having a hinged bezel.

### BACKGROUND OF THE INVENTION

Electrical, electronic and other similar devices are typically contained in a housing, frame, chassis, case, enclosure, and or the like (hereinafter referred to as an enclosure). Access is typically required, to the components, parts, and the like contained inside the enclosure, for repair, upgrade, service and the like.

Referring to FIGS. 1 and 2, an enclosure 105 in accordance with the conventional art is shown. As depicted in FIG. 1, the front of the enclosure 105, typically includes one or more covers, doors, tops, bezels, and or the like (hereinafter referred to as bezels) 110, 115. The bezels 110, 115 provide access through the front of the enclosure 105. The bezels 110, 115 may also provide additional functionality. For example, the bezels 110, 115 typically provide an aesthetically pleasing appearance of the enclosure 105. The bezels 110, 115 may also provide for viewing of particular areas on and/or within the enclosure 105. The bezels 110, 115 may also provide protection, for the enclosure and the components and parts therein, against damage. The bezels 110, 115 may also direct airflow for cooling, provide electromagnetic shielding, and/or the like.

One or more bezels 110, 115 are typically pivotally attached along an edge (e.g., top, bottom, or side) of the enclosure 105. In normal use, the bezels 110, 115 are intended to be in a closed position covering a face (e.g., front) of the enclosure 105. The bezels 110, 115 may be opened to access the interior of the enclosure 105.

One method, according to the conventional art, of attaching the bezels 110, 115 to the enclosure utilizes snap tabs. The bezels 110, 115 may be snapped onto and/or off of the enclosure 105 with the use of the tabs. Unsnapping the bezels 110, 115 from the enclosure provides unrestricted access to the interior of the enclosure 105. However, the detached bezels 110, 115 can readily be lost, damaged, or simply not reattached after servicing. As a result, the aesthetic and functional benefits of the bezels 110, 115 are lost.

As depicted in FIG. 2, another method, according to the conventional art, of attaching the bezels 210, 215 to the enclosure 205 utilizes one or more hinges 220, 225. The pivot points of the hinges 220, 225 are typically positioned at the edge of the enclosure 205. The hinge 220, 225 positioned at the edge of the enclosure 205 allows the bezels 210, 215 to be opened more than ninety degrees, with respect to the adjacent surface of the enclosure 205. The hinge 220, 225 method also provides a substantially permanent method of securing the bezels 220, 225 to the enclosure. Thus, the bezels 210, 215 are unlikely to be lost, damaged or simply not reattached after servicing. However, the bezels 210, 215 project past the profile of the enclosure 205. As a result, adjacent structures such as supporting tables, shelves and additional enclosures may obstruct the travel of the bezels 210, 215, thereby preventing the bezels 210, 215 from opening fully. If the hinge 220, 225 are moved a distance in from the edge of the enclosure 205, the side of the bezels 210, 215 will swing toward the enclosure 205. Thus, the enclosure 205 itself will prevent the bezels 210, 215 from opening more than ninety degrees. Furthermore, the hinge method does not provide an option of readily removing the bezels 210, 215 when necessary.

Thus, there is a need for an assembly that allows the bezel to open without being restricted by an adjacent object. The assembly should also allow the bezel to open without being restricted by a surface to which it is attached. There is also a need for the assembly to permit the bezel to rotate more then 90° between a closed position and an open position. Furthermore, there is a need for an assembly that readily provides for captive installation and removal when necessary.

### SUMMARY OF THE INVENTION

Embodiments of the present invention provide an improved bezel assembly. In one embodiment of the present invention, a bezel assembly comprising a bezel having a pair of receiving members oppositely disposed about one side of the bezel. The bezel assembly also comprises a mounting member. The mounting member comprises a body and a pair of engaging arms oppositely disposed at each end of the body. The engaging arms are captively engaged by the receiving members.

In another embodiment of the present invention, a bezel assembly comprises a bezel and a mounting member. The bezel comprises a pair of receiving members having oppositely disposed receptacles. The mounting member comprises a pair of engaging arms. Each engaging arm has a pivot pin. The pivot pins are captively engaged by the receptacle.

Embodiments of the present invention are advantageous in that the mounting member provides for operable obtuse pivoting about a footprint of said mounting member. Furthermore, embodiments of the present invention are also advantageous in that the captive bezel reduces the need to remove the bezel. Thus, the bezel is less likely to be damaged because it remains part of the structure during servicing. The bezel is also less likely to be left off of the structure during servicing, thus affecting the aesthetic appearance of the structure. The bezel is also less likely to be left off the structure, thus degrading safety. The bezel is also less likely to be left off the structure, thus affecting electromagnetic interference shielding. The bezel is also less likely to be left off the structure, thus affecting ventilation. Embodiment of the present invention are also advantageous in that, when in a closed position, the hinge provides an aesthetically pleasing appearance.

### BRIEF DESCRIPTION OF THE DRAWINGS

The present invention is illustrated by way of example and not by way of limitation, in the figures of the accompanying drawings and in which like reference numerals refer to similar elements and in which:

Prior art FIG. 1 shows an enclosure in accordance with the conventional art.

Prior art FIG. 2 shows an enclosure in accordance with the conventional art.

FIG. 3 shows a perspective view of a mounting member, in accordance with one embodiment of the present invention.

FIGS. 4A-4C show a plurality of views of an engaging arm, in accordance with one embodiment of the present invention.

FIG. 5 shows a partial perspective view of a bezel, in accordance with one embodiment of the present invention.

FIGS. 6A-6C show a plurality of views of a receiving member, in accordance with one embodiment of the present invention.

FIG. 7 shows a partial perspective view of a bezel assembly, in accordance with one embodiment of the present invention.

FIGS. 8A-8C show partial sectional views of an bezel assembly, in accordance with one embodiment of the present invention.

FIG. 9 shows a perspective view of one or more bezel assemblies attached to an enclosure, in accordance with one embodiment of the present invention.

FIG. 10 shows a partial perspective view of a bezel assembly attached to an enclosure, in accordance with one embodiment of the present invention.

### DETAILED DESCRIPTION OF THE INVENTION

Reference will now be made in detail to the embodiments of the invention, examples of which are illustrated in the accompanying drawings. While the invention will be described in conjunction with the preferred embodiments, it will be understood that they are not intended to limit the invention to these embodiments. On the contrary, the invention is intended to cover alternatives, modifications and equivalents, which may be included within the spirit and scope of the invention as defined by the appended claims. Furthermore, in the following detailed description of the present invention, numerous specific details are set forth in order to provide a thorough understanding of the present invention. However, it will be obvious to one of ordinary skill in the art that the present invention may be practiced without these specific details. In other instances, well-known methods, procedures, components, and circuits have not been described in detail as not to unnecessarily obscure aspects of the present invention.

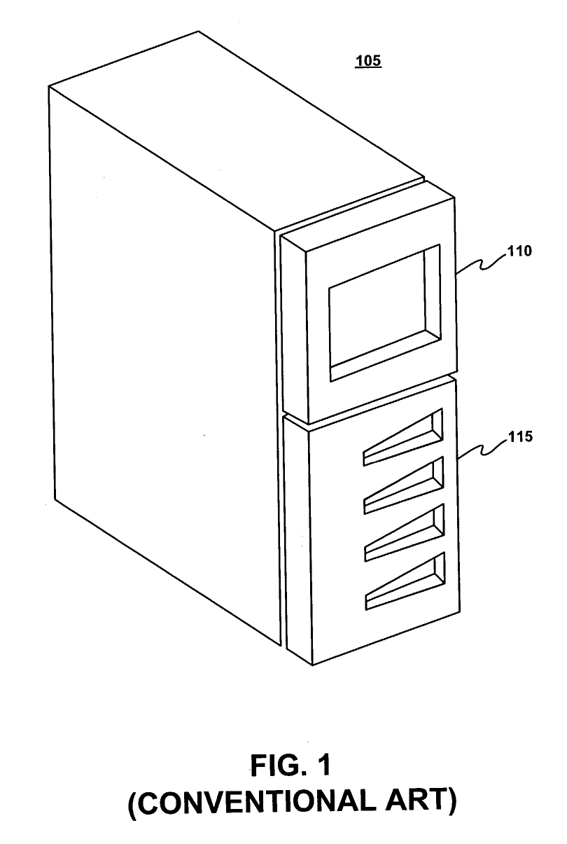

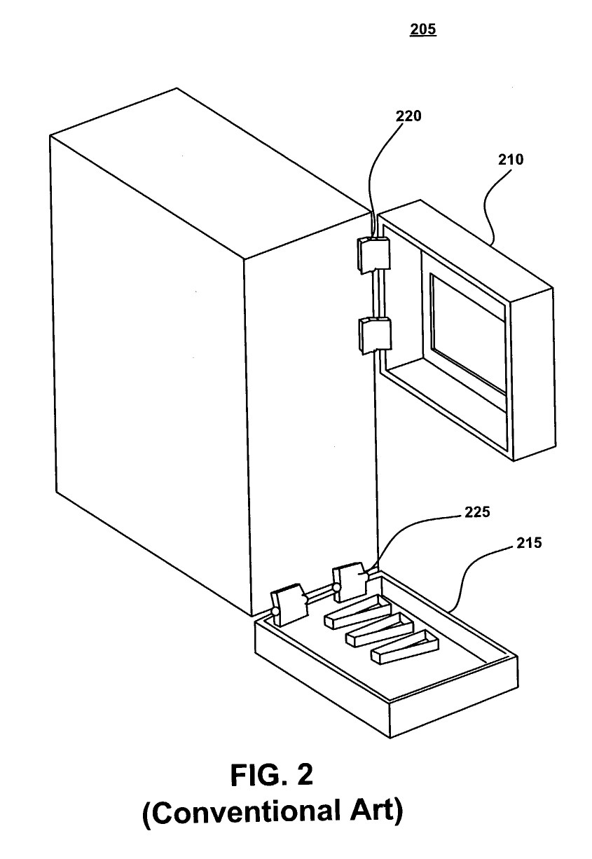

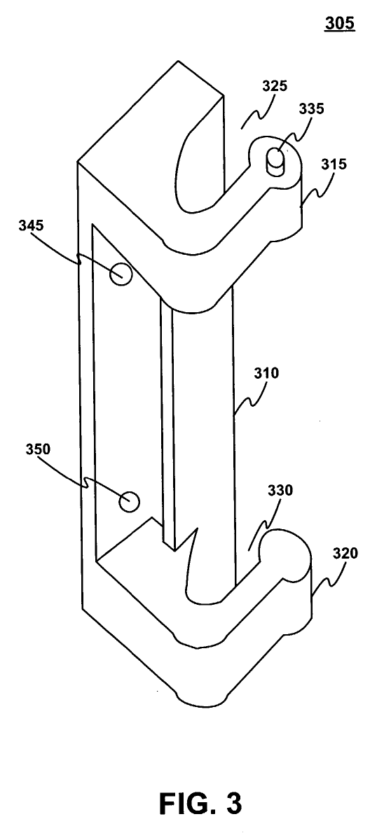

Referring now to FIG. 3, a perspective view of a mounting member 305, in accordance with one embodiment of the present invention, is shown. As depicted in FIG. 3, the mounting member 305 comprises a body 310 and a pair of engaging arms 315, 320 disposed at opposite ends of the body 310. The engaging arms 315, 320 are disposed with respect to the body 310 so as to form distorted u-shaped receiving spaces 325, 330. Each engaging arm 315, 320 also has an enlarged terminus with an pivot pin 335 formed thereon. Each pivot pin 335 extends outwardly, with respect to the ends of the body 310.

The body 310 may also comprise one or more attaching means 345, 350. In one implementation, the attaching means 345, 350 may be holes for receiving fasteners, such as screws, rivets, tabs, and the like.

In one implementation, the mounting member 305 is formed by an injection molding process from a plastic material.

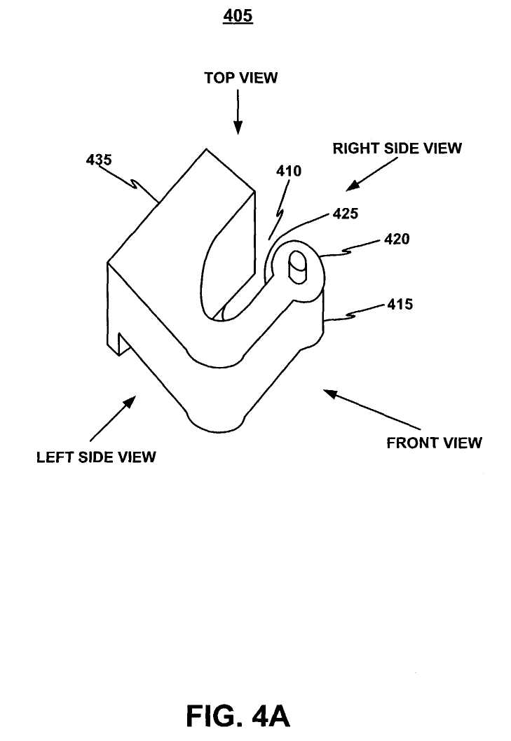

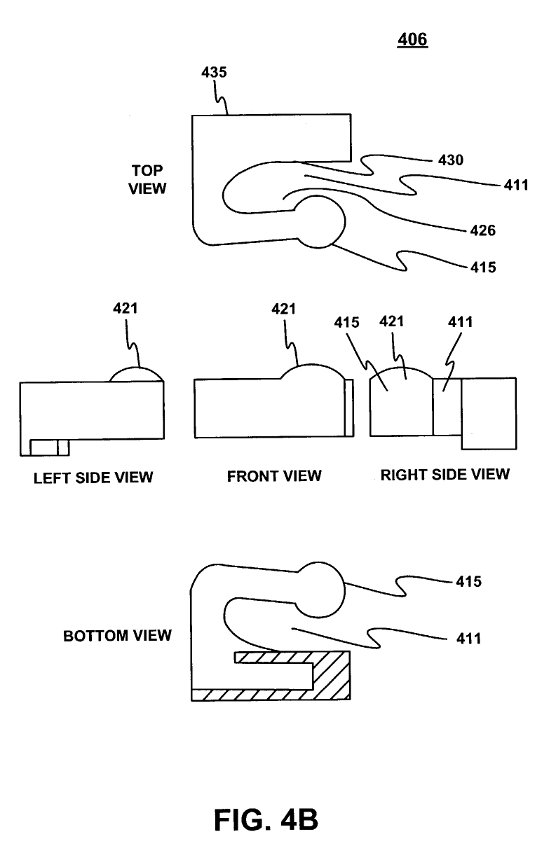

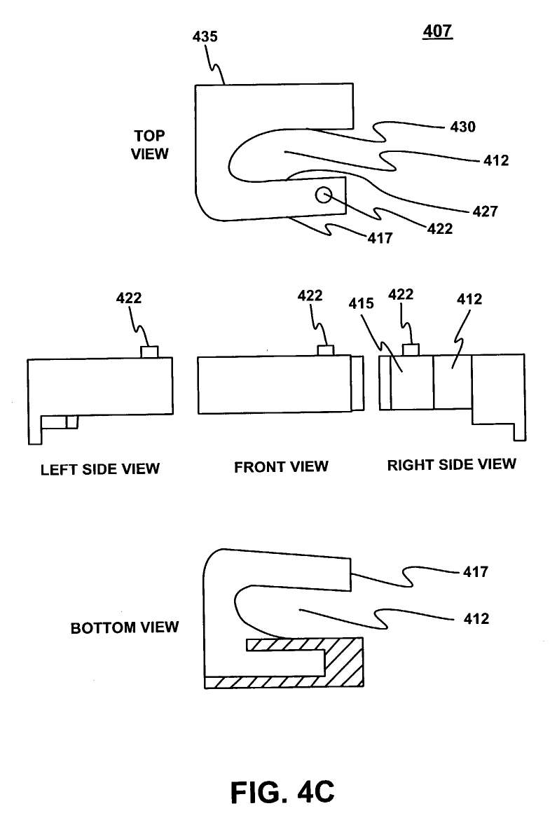

Referring now to FIGS. 4A-4C, a plurality of views of an engaging arm 405 in accordance with one embodiment of the present invention, is shown. As depicted in FIG. 4A, the engaging arm 405 has an enlarged terminus 415 with a pivot protrusion 420 disposed thereon. The enlarged terminus 415 may be substantially cylindrical. The pivot pin 420 extends outwardly from the engaging arm 405. The pivot protrusion 420 may be substantially cylindrical.

The engaging arm 405 forms a distorted u-shaped receiving space 410. One portion of the receiving space 410 comprises a recess 425 formed by the enlarged terminus 415. Another portion of the receiving space 430 comprises an irregular curvature 430 along a body 435.

As depicted in FIG. 4B, a top view, a left side view, a front view, and right side view of another implementation of an engaging arm 406 is shown. The engaging arm 406 has an enlarged terminus 415 with an engaging protrusion 421 disposed thereon. The engaging arm 406 is angled in slightly, thus hooking back on itself. The enlarged terminus 415 may be substantially cylindrical. The engaging protrusion 421 extends outwardly from the engaging arm 406. The engaging protrusion 421 may be substantially hemispherical.

The engaging arm 406 forms a distorted u-shaped receiving space 411. One portion of the receiving space 411 comprises a recess 426 formed by the slightly inward angled engaging arm 406 and the enlarged terminus 415. Another portion of the receiving space 411 comprises an irregular curvature 430 along a body 435.

As depicted in FIG. 4C, a top view, a left side view, a front view, and right side view of another implementation of the engaging arm 407 is shown. The engaging arm 407 has a terminus 417 with an pivot pin 422 disposed thereon. The engaging arm 407 is angled in slightly, thus hooking back on itself. The pivot pin 422 extends outwardly from the engaging arm 407. The pivot pin 422 may be substantially cylindrical.

The engaging arm 407 forms a distorted u-shaped receiving space 412. One portion of the receiving space 412 comprises a recess 427 formed by the slightly inward angled engaging arm. Another portion of the receiving space 412 comprises an irregular curvature 430 along a body 435.

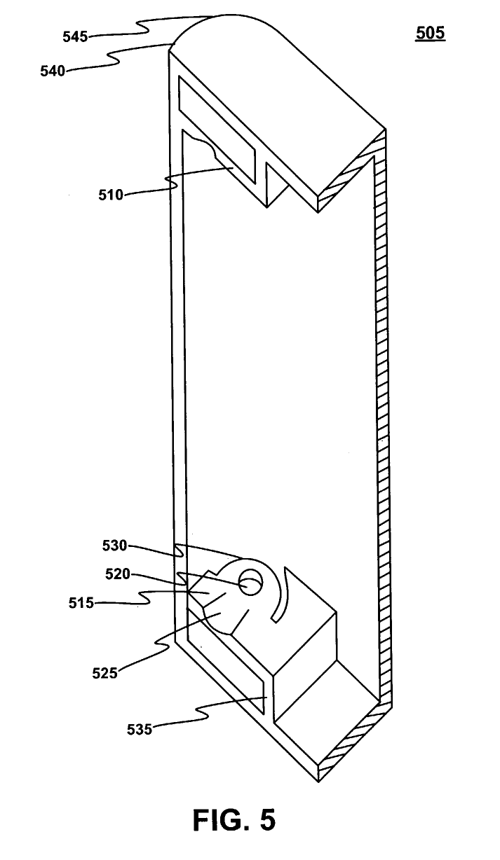

Referring now to FIG. 5, a partial perspective view of a bezel 505 in accordance with one embodiment of the present invention is shown. As depicted in FIG. 5, the bezel 505 comprises a pair of receiving members 510, 515. The receiving member 510, 515 are disposed at opposite ends of the interior of the bezel 505 along one side 540. The bezel 505 has a rounded corner 545 along the length of the one side 540.

In one implementation, both receiving members 510, 515 comprise a receptacle 520 and an insertion guide 525. The receiving members 510, 515 may optionally be slanted to form a ramp 530. The receiving member 510, 515 may also optionally be formed upon a spacer structure 535.

In another implementation (not shown), a first receiving member 515 comprises a receptacle 520 formed in a sidewall of the bezel. A second receiving member 515 comprises a receptacle 520 and an insertion guide 515 formed on a ramp 530.

In another implementation, the receiving members 510, 515 are integrally formed in the bezel 505. In an exemplary implementation, the receiving member 510, 515 and the bezel are integrally formed by an injection molding process from a plastic material. In another implementation, the receiving members 510, 515 are coupled to the bezel 505.

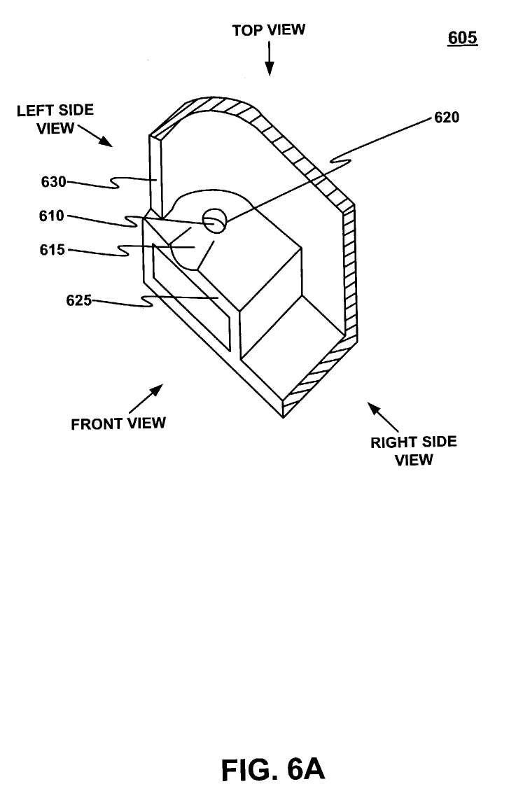

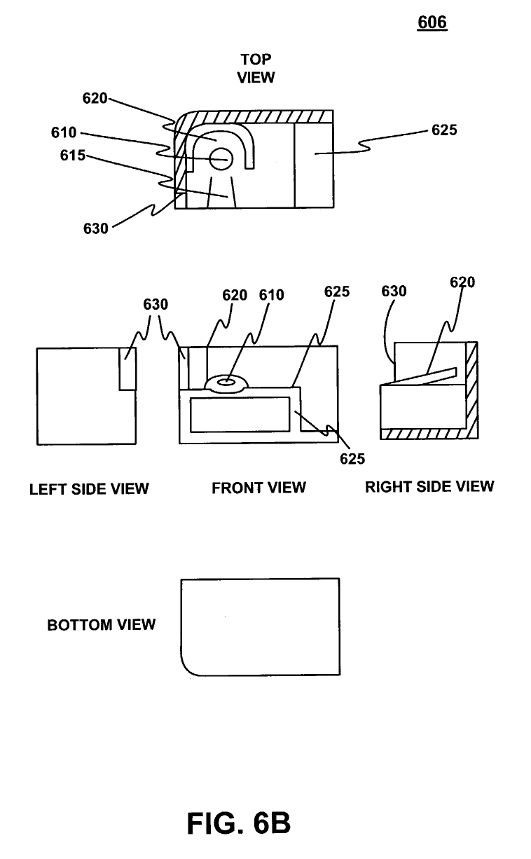

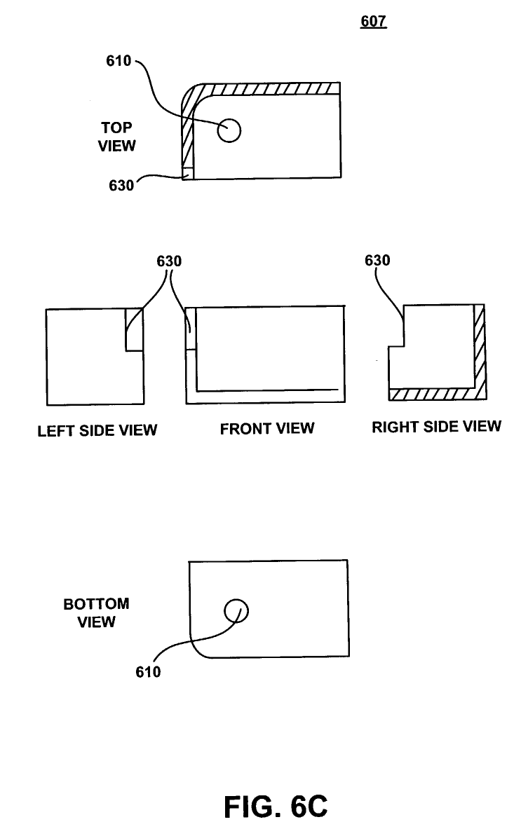

Referring now to FIGS. 6A-6C, a plurality of views of a receiving member 605, in accordance with one embodiment of the present invention, is shown. As depicted in FIG. 6A, a perspective view of the receiving member 605 is shown. The receiving member 605 comprises a receptacle 610 and an insertion guide 615. The receiving member 605 may also optionally be formed upon a spacer structure 625.

As depicted in FIG. 6B, a top view, a left side view, a front view, and a right side view of another implementation of a receiving member 606 is shown. The receiving member 606 comprises a receptacle 610 and an insertion guide 615. The receiving member 605 is also partially slanted to form a ramp 620. The receiving portions may also optionally be formed upon a spacer structure 625.

As depicted in FIG. 6C, a top view, a left side view, a front view, and a right side view of another implementation of a receiving member 607 is shown. The receiving member 607 comprises a receptacle 610 formed in a sidewall of a bezel. In another implementation, the receiving member 607 comprises a receptacle 610 formed in a spacer.

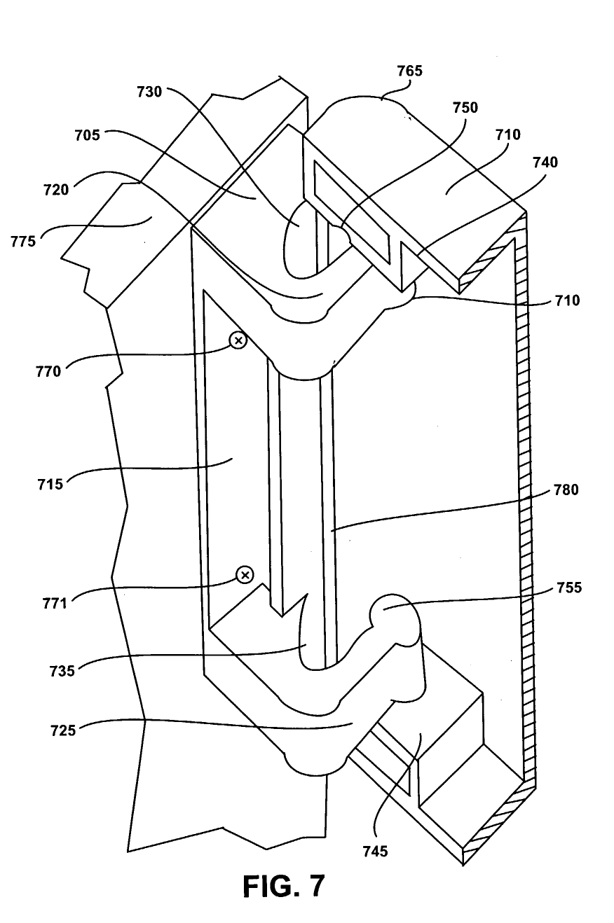

Referring now to FIG. 7, a partial perspective view of a bezel assembly 700, in accordance with one embodiment of the present invention, is shown. As depicted in FIG. 7, the bezel assembly 700 comprises a bezel 710 and a mounting member 705. The mounting member 705 is comprises of an elongated body 715 having a pair of engaging arms 720, 725 disposed at opposite ends thereof. The engaging arms 720, 725 each form a distorted u-shaped receiving space 730, 735.

The bezel 710 comprises a pair of receiving members 740, 745 disposed at opposite ends of the interior of the bezel 710. A corner of the bezel 710, adjacent the receiving members 740, 745, is rounded 765. Both receiving portions 740, 745 are comprised of a receptacle (not visible) and an insertion guide 750. A portion of a sidewall, along one edge, of a bezel may also be recessed 780.

The engaging arms 720, 725, of the engaging member 705, are disposed proximate the receiving members 740, 745 of the bezel 710. The receptacle of each receiving member 740, 745 receives a pivot pin (not visible) of each engaging arm 740, 745. The receptacles captively retain the pivot pins, while allowing the bezel 710 to pivot about a terminus 755, 760 of each engaging arm 720, 725.

A pair of receiving spaces 730, 735 formed between the elongated body 715 and the engaging structure 705 provide for extended travel of the one edge of the bezel 710. In addition, the rounded corner 765 of the bezel 710 also provide for extended travel of the one edge of the bezel 710. Thus, the bezel 710 may pivot about the engaging arms 720, 725 by ninety degree or more (e.g., obtuse pivoting), while remaining substantially within the footprint of the engaging structure 705.

The mounting member 705 and the bezel 710 may be assembled by aligning the pin on each engaging arm 720, 725 proximate the start of the insertion guides 750. The engaging arms 720, 725 are then operably directed along the insertion guides 750, until the pins on the engaging arms 720, 725 are captured by the receptacles of the receiving members 740, 745.

The receiving members 740, 745 and/or mounting member 705 may be fabricated from a flexibly resilient material. The resilient engaging arms of the mounting member act as a shock absorber when the bezel is opened or closed with an excess of force. The flexible ramped receiving members 740, 745 act as a spring for snapping the bezel 710 on and off. Thus, the mounting member 705 and bezel 710 may readily be assembled. The mounting member 705 and bezel 710 may also be disassembled, if necessary, by flexing the ramps until the pins of the engaging arms 720, 725 are released.

The mounting member 705 may also comprise one or more structures 770-771 for attaching to an enclosure 775. In one implementation, the attaching structures 770-771 may be holes for receiving fasteners, such as screws, rivets, tabs, and the like.

In another implementation, the bezel 710 comprises a first and second receiving member. The first receiving member comprises a receptacle. The second receiving member 740 comprises a receptacle disposed on a ramp and having an insertion guide 750. The mounting member 705 and the bezel 710 may be assembled by inserting a first pivot pin on one engaging arm 725 into the first receiving member. A second pivot pin on a second engaging arm 720 is then aligned proximate the insertion guide 750 of the second receiving member 740. The second pivot pin is then operably directed along the insertion guide until the pin is captured by the receptacle of the second receiving member 740.

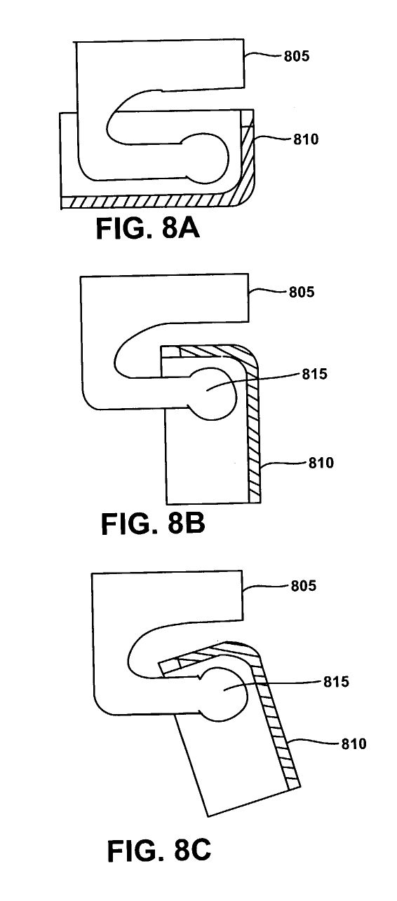

Referring now to FIGS. 8A-8C, partial sectional views of an bezel assembly, in accordance with one embodiment of the present invention, is shown. The bezel assembly comprises a bezel and mounting member. As depicted in FIG. 8A, the bezel is located in a first position (e.g., a closed position). As depicted in FIG. 8B, the bezel is located in a second position (e.g., an open position). The bezel is pivoted about the terminus of an engaging arm, as compared with FIG. 8A. As depicted in FIG. 8C, the bezel is located in a third position (e.g., an extended open position). Again the bezel is further pivoted about the terminus of the engaging arm, as compared with FIG. 8C. FIGS. 8A through 8C illustrate the bezel 810 obtusely pivoting (e.g., pivoting 90 or more degrees) about a terminus 815 of an engaging arm 805.

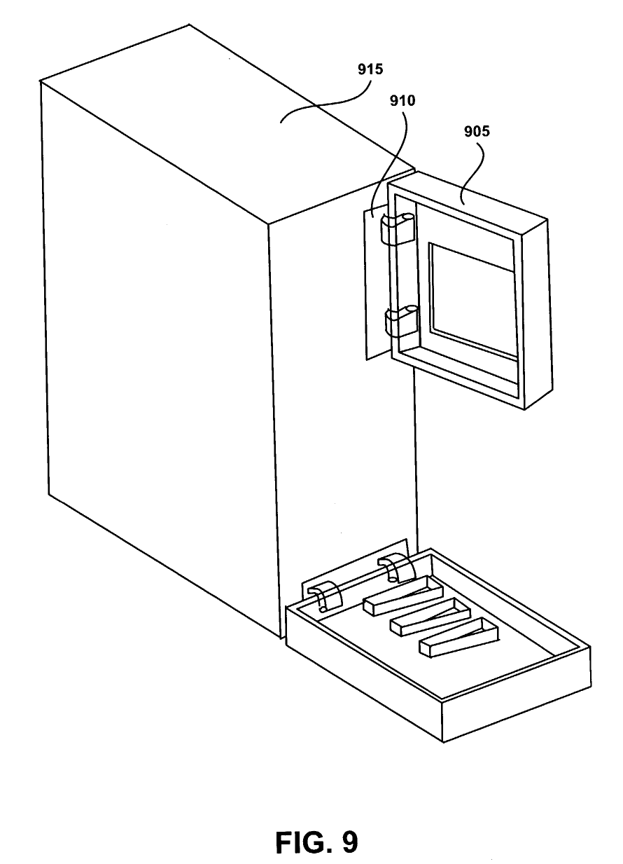

Referring now to FIG. 9, a perspective view of one or more bezel 905 assemblies attached to an enclosure, in accordance with one embodiment of the present invention, is shown. As depicted in FIG. 9, one or more bezels 905 may be attached, to the enclosure 915, by a respective mounting member 910. The mounting member 910 may be positioned along a bottom edge, side edge, top edge or any other desired location.

The mounting member 910 allows the bezel 905 to open ninety or more degrees (herein referred to as obtuse pivoting). The captured edge of the bezel 905 remains substantially within the footprint of the mounting member 910 as it travels from a closed position to a fully open position, and vice-versa. The present embodiment is advantageous in that the enclosure does not have to be moved to open the bezel, thus reducing stress on cables attached to the enclosures.

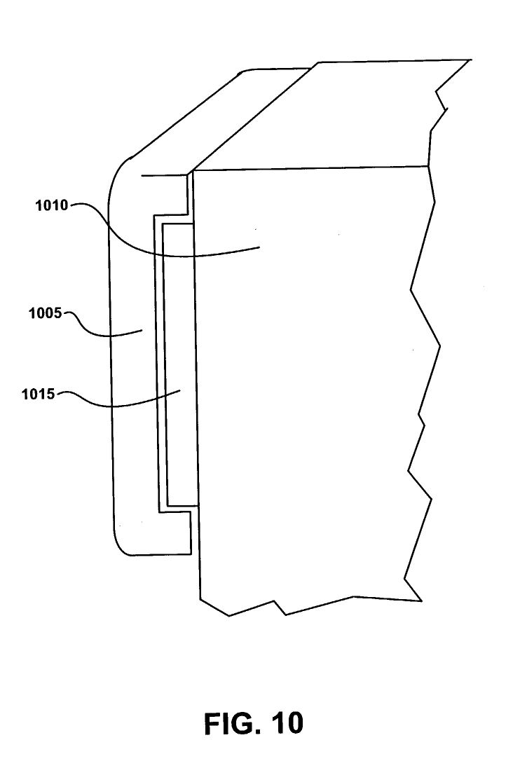

Referring now to FIG. 10, a partial perspective view of a bezel assembly attached to an enclosure, in accordance with one embodiment of the present invention, is shown. As depicted in FIG. 10, a bezel 1005 is attached to an enclosure 1010 by a mounting member 1015. When the bezel 1005 is in a closed position, only a uniform face of the mounting member 1015 is visible. The mounting member 1015 may be fabricated from the same material as the bezel 1005 and/or enclosure 1010. The mounting member 1015 may also be fabricated having the same color as the bezel 1005 and/or enclosure 1010. Thus, the exposed uniform face of the mounting member 1015 provides a pleasing aesthetic appearance.

The foregoing descriptions of specific embodiments of the present invention have been presented for purposes of illustration and description. They are not intended to be exhaustive or to limit the invention to the precise forms disclosed, and obviously many modifications and variations are possible in light of the above teaching. The embodiments were chosen and described in order to best explain the principles of the invention and its practical application, to thereby enable others skilled in the art to best utilize the invention and various embodiments with various modifications as are suited to the particular use contemplated. It is intended that the scope of the invention be defined by the claims appended hereto and their equivalents.

What is claimed is:

1. A bezel assembly comprising:
a bezel including;
a first receiving member disposed about a first side of said bezel, wherein said first receiving member comprises a first receptacle;
a second receiving member disposed about said first side of said bezel opposite said first receiving member, wherein said second receiving member comprises a second receptacle;
a mounting member including;
a body;
a first engaging arm disposed at a first end of said body;
a second engaging arm, disposed at a second end of said body; and
wherein said mounting member provides for operable obtuse pivoting of said bezel about a footprint of said mounting member.

2. The bezel assembly according to claim 1, wherein said mounting member further comprises:
a first pivot pin disposed about said first engaging arm, wherein said first pivot pin is captively engaged by said first receptacle; and
a second pivot pin disposed about said second engaging arm, wherein said second pivot pin is captively engaged by said second receptacle.

3. The bezel assembly according to claim 1, wherein said bezel further comprises a first insertion guide, wherein said first pivot pin is operably directed to said receptacle.

4. The bezel assembly according to claim 1, wherein said first engaging arm and second engaging arm provides for absorbing excess force applied to said bezel.

5. The bezel assembly according to claim 1, wherein said first receiving member is coupled to a sidewall of said bezel by a spacer

6. The bezel assembly according to claim 5, wherein said second receiving member is integrally formed in a sidewall of said bezel.

7. The bezel assembly according to claim 1, wherein said mounting member provides an exposed flat face and improves aesthetic appearance.

8. A mounting member comprising:
a body;
a first engaging arm disposed at a first end of said body;
a first engaging protrusion disposed about said first engaging arm proximate said first end of said body;
a second engaging arm disposed at a second end of said body; and
a second engaging protrusion disposed about said second engaging arm proximate said second end of said body.

9. The mounting member according to claim 8, wherein said first engaging arm and said body form a first receiving space, and wherein said second engaging arm and said body form a second receiving space.

10. The mounting member according to claim 9, wherein said first receiving space comprises a distorted u-shaped slot, and wherein said second receiving space comprises a distorted u-shaped slot.

11. The mounting member according to claim 10, wherein said first receiving space and said second receiving space provide for obtuse pivoting of a bezel coupled to said mounting member.

12. The mounting member to claim 8, wherein said mounting member is comprised of a resilient material.

13. A bezel comprising:
a first receiving member, disposed proximate a first side of said bezel;
a first receptacle, disposed about said first receiving member;
a second receptacle, disposed proximate said first side of said bezel opposite said first receptacle.

14. The bezel according to claim 13, wherein a corner proximate said first side of said bezel is rounded.

15. The bezel according to claim 14, wherein said rounded corner provides for obtuse pivoting of said bezel about a mounting member.

16. The bezel according to claim 13, wherein an edge proximate said first side of said bezel is recessed.

17. The bezel according to claim 16, wherein said recessed edge proximate said first side of said bezel provides for obtuse pivoting of said bezel about a mounting member.

18. The bezel according to claim 13, wherein said first receiving member is angularly disposed to form a first ramp.

19. The bezel according to claim 18, wherein said first ramp provides for operable capture of a pivot pin of a mounting member.

20. The bezel according to claim 13, wherein said first receiving member is comprised of a flexible material.
